(19) United States
(12) Patent Application Publication
(10) Pub. No.: US 2022/0129728 A1
(43) Pub. Date: Apr. 28, 2022

(54) REINFORCEMENT LEARNING-BASED RECLOSER CONTROL FOR DISTRIBUTION CABLES WITH DEGRADED INSULATION LEVEL

(71) Applicants: Qiushi Cui, Tempe, AZ (US); Yang Weng, Chandler, AZ (US)

(72) Inventors: Qiushi Cui, Tempe, AZ (US); Yang Weng, Chandler, AZ (US)

(73) Assignee: Arizona Board of Regents on behalf of Arizona State University, Scottsdale, AZ (US)

(21) Appl. No.: 17/511,124

(22) Filed: Oct. 26, 2021

Related U.S. Application Data
(60) Provisional application No. 63/105,629, filed on Oct. 26, 2020.

(51) Int. Cl. G06N 3/04; G01R 31/08; G06N 20/00

(52) U.S. Cl. CPC G06N 3/04; G06N 20/00; G01R 31/088; G01R 31/085

(57) ABSTRACT

Reinforcement learning (RL)-based recloser control for distribution cables with degraded insulation level is provided. Utilities continuously observe cable failures on aged cables that have an unknown degraded basic insulation level (BIL). One of the root causes is the transient overvoltage (TOV) associated with circuit breaker reclosing. Since it is hard to model TOV due to its complexity, embodiments described herein provide a model-free stochastic control method for reclosers under the existence of uncertainty and noise. Concretely, to capture high-dimensional dynamics patterns, the recloser control problem is formulated herein by incorporating the temporal sequence reward mechanism into a deep Q-network (DQN). Meanwhile, physical understanding of the problem is embedded into the action probability allocation to develop an infeasible-action-space-elimination algorithm. The learning efficiency is proved to be outstanding due to the proposed time sequence reward mechanism and infeasible action elimination method.

### RELATED APPLICATIONS

This application claims the benefit of provisional patent application Ser. No. 63/105,629, filed Oct. 26, 2020, the disclosure of which is hereby incorporated herein by reference in its entirety.

### GOVERNMENT SUPPORT

This invention was made with government funds under 1810537 awarded by the National Science Foundation. The U.S. Government may have rights in this invention.

### FIELD OF THE DISCLOSURE

The present disclosure relates to protection circuits for power distribution networks.

### BACKGROUND

A switching voltage surge or transient in a power distribution system is the result of energization or de-energization of transmission or distribution lines and large electrical apparatuses, such as reactors and capacitor banks. These actions can occur in the system due to system configuration changes or faults. During these conditions, the inductive or capacitive loads release or absorb the energy suddenly and generate voltage or current transient. Consequently, voltage surges may occur and, therefore, jeopardize the equipment and personal safety. Specifically, the switching surges usually occur upon the energization of lines, cables, transformers, reactors, or capacitor banks.

Long high-voltage lines store a large amount of energy, which generates many voltage transients in the systems. Capacitance in a transmission line causes current to flow even when no load is connected to the line, which is referred to as line charging current. Underground line capacitance for power cables is far higher as compared to their overhead counterparts due to closeness of the cables and proximity to earth. As a result, underground lines have 20-75 times the line charging current. Thus, cables can trap a high amount of charge. The trapped charge is a residual charge in the line or cable subsequent to de-energization. If the trapped charge has the same polarity as the system voltage, switching overvoltage may be observed.

FIG. 1A is a photograph of a faulted cable after five recloses. FIG. 1B is a photograph of an unfaulted cable adjacent to the faulted cable of FIG. 1A that has similar damage. Although most papers focus on transient overvoltage (TOV) in transmission lines, cable failures due to TOV are continuously reported by utilities. In fact, a slow TOV whose duration is less than a cycle should not be a problem for insulation of a line as the cable basic insulation level (BIL) is much higher. However, most aged cables have unknown and degraded BIL, causing frequent cable failures in modern smart grids. Besides, most utilities probably do not reclose into faults on underground systems, as faults in underground systems are considered permanent. The purpose of reclosing is to allow temporary faults to be cleared, which is typical for an overhead system. However, the effects of reclosing into underground faults are largely unstudied.

### SUMMARY

Reinforcement learning (RL)-based recloser control for distribution cables with degraded insulation level is provided. Utilities continuously observe cable failures on aged cables that have an unknown degraded basic insulation level (BIL). One of the root causes is the transient overvoltage (TOV) associated with circuit breaker reclosing. To solve this problem, researchers have proposed a series of controlled switching methods, most of which use deterministic control schemes. However, in power systems, especially in distribution networks, the switching transient is buffeted by stochasticity. Since it is hard to model TOV due to its complexity, embodiments described herein provide a model-free stochastic control method for reclosers under the existence of uncertainty and noise.

Concretely, to capture high-dimensional dynamics patterns, the recloser control problem is formulated herein by incorporating the temporal sequence reward mechanism into a deep Q-network (DQN). Meanwhile, physical understanding of the problem is embedded into the action probability allocation to develop an infeasible-action-space-elimination algorithm. Through power system computer-aided design (PSCAD) simulation, the impact of load types on cables' TOVs is revealed. Then, to reduce the training burden for the proposed RL control method in different applications, a post-learning knowledge transfer method is established. After validation, several learning curves are exhibited to show the enhanced performance. The learning efficiency is proved to be outstanding due to the proposed time sequence reward mechanism and infeasible action elimination method. Moreover, the results on knowledge transfer demonstrate the capability of method generalization. Finally, a comparison with conventional methods is conducted, which illustrates the proposed method is most effective in mitigating the TOV phenomenon among three methods.

An exemplary embodiment provides a method for recloser control in a power distribution system. The method includes developing an RL-based framework for recloser control in a stochastic environment and controlling a recloser using the developed RL-based framework.

Another exemplary embodiment provides a recloser controller. The recloser controller includes a processing device and a memory comprising a set of instructions which, when executed by the processing device, cause the recloser controller to develop a state, action, and reward of an RL-based framework to mitigate reclosing TOV in a recloser.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a photograph of a faulted cable after five recloses.

FIG. 1B is a photograph of an unfaulted cable adjacent to the faulted cable of FIG. 1A that has similar damage.

FIG. 2A is a graphical representation of an example of the transient overvoltage (TOV) waveform for a distributed line model plotted using power system computer-aided design (PSCAD) when the reclosing angle is set at 0°.

FIG. 2B is a graphical representation of the TOV waveform of FIG. 2A when the reclosing angle is set at 45°.

FIG. 2C is a graphical representation of the TOV waveform of FIG. 2A when the reclosing angle is set at 90°.

FIG. 2D is a graphical representation of the TOV waveform of FIG. 2A when the reclosing angle is set at 180°.

FIG. 3A is a graphical representation of an example of the TOV waveform for a frequency-dependent π model plotted using PSCAD when the reclosing angle is set at 0°.

FIG. 3B is a graphical representation of the TOV waveform of FIG. 3A when the reclosing angle is set at 45°.

FIG. 3C is a graphical representation of the TOV waveform of FIG. 3A when the reclosing angle is set at 90°.

FIG. 3D is a graphical representation of the TOV waveform of FIG. 3A when the reclosing angle is set at 180°.

FIG. 4 is a schematic diagram of an exemplary recloser controller illustrating its reward design.

FIG. 5A is a graphical representation of action-reward pairs without time sequence-based reward design for five breaker operations.

FIG. 5B is a graphical representation of action-reward pairs with time sequence-based reward design for five breaker operations.

FIG. 5C is a graphical representation of the cumulative rewards for the designs of FIGS. 5A and 5B.

FIG. 6 is a schematic diagram of an exemplary approach to learning a reward function along with an agent by fitting the reward to a polynomial function.

FIG. 7 is a schematic diagram of an exemplary benchmark power distribution system used for evaluating embodiments described herein.

FIG. 8 is a graphical representation of a learning curve that shows the individual episode reward, average reward, and Q value at the beginning of each episode named episode Q₀.

FIG. 9A is a graphical representation of the effect of the discounting factor γ on the breaker controlling reward.

FIG. 9B is a graphical representation of the effect of the E value on the breaker controlling reward.

FIG. 9C is a graphical representation of the effect of the decay rate on the breaker controlling reward.

FIG. 9D is a graphical representation of the effect of the smoothing factor τ on the breaker controlling reward.

FIG. 9E is a graphical representation of the effect of the experience buffer D on the breaker controlling reward.

FIG. 9F is a graphical representation of the effect of the minimum batch size M on the breaker controlling reward.

FIG. 10 is a graphical representation of a learning curve comparison with and without the infeasible action eliminated.

FIG. 11 is a graphical representation of a comparison of the proposed methodology with both traditional methods.

FIG. 12 is a flow diagram illustrating a process for recloser control in a power distribution system.

FIG. 13 is a block diagram of a recloser controller suitable for implementing reinforcement learning (RL)-based recloser control for distribution cables with degraded insulation level according to embodiments disclosed herein.

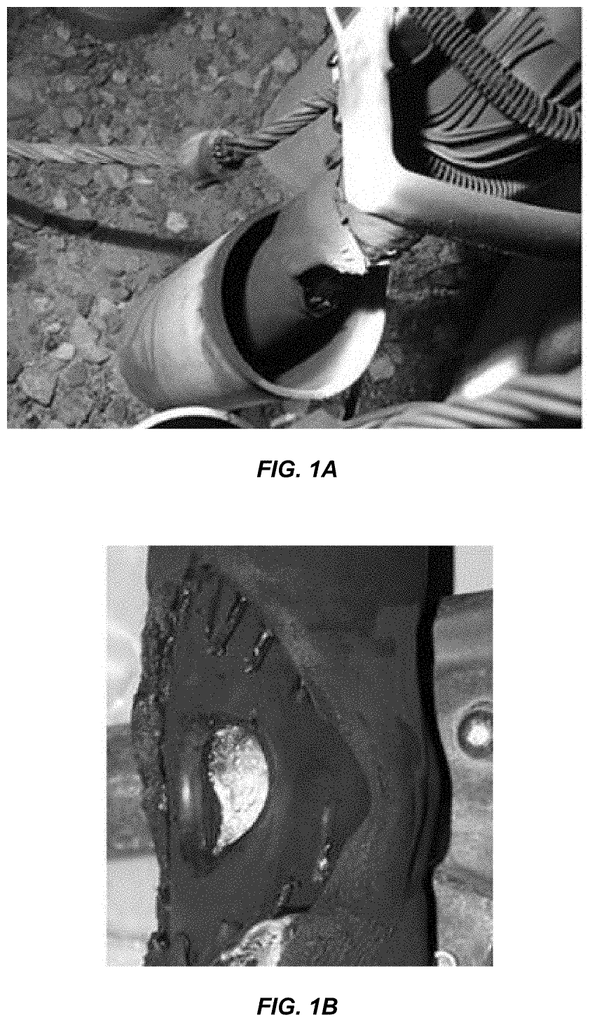

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Reinforcement learning (RL)-based recloser control for distribution cables with degraded insulation level is provided. Utilities continuously observe cable failures on aged cables that have an unknown degraded basic insulation level (BIL). One of the root causes is the transient overvoltage (TOV) associated with circuit breaker reclosing. To solve this problem, researchers have proposed a series of controlled switching methods, most of which use deterministic control schemes. However, in power systems, especially in distribution networks, the switching transient is buffeted by stochasticity. Since it is hard to model TOV due to its complexity, embodiments described herein provide a model-free stochastic control method for reclosers under the existence of uncertainty and noise.

Concretely, to capture high-dimensional dynamics patterns, the recloser control problem is formulated herein by incorporating the temporal sequence reward mechanism into a deep Q-network (DQN). Meanwhile, physical understanding of the problem is embedded into the action probability allocation to develop an infeasible-action-space-elimination algorithm. Through power system computer-aided design (PSCAD) simulation, the impact of load types on cables' TOVs is revealed. Then, to reduce the training burden for the proposed RL control method in different applications, a post-learning knowledge transfer method is established. After validation, several learning curves are exhibited to show the enhanced performance. The learning efficiency is proved to be outstanding due to the proposed time sequence reward mechanism and infeasible action elimination method. Moreover, the results on knowledge transfer demonstrate the capability of method generalization. Finally, a comparison with conventional methods is conducted, which illustrates the proposed method is most effective in mitigating the TOV phenomenon among three methods.

I. Introduction

As described above, most aged cables in power distribution systems have unknown and degraded BIL, causing frequent cable failures in modern smart grids. Most utilities probably do not reclose into faults on underground systems, as faults in underground systems are considered permanent. One aspect of the present disclosure investigates what damaging effects reclosing into underground faults may produce and provides arguments to change this practice. Therefore, the effects of reclosing (in particular, the resulting overvoltage phenomenon in distribution systems) are investigated for the practical consideration of eliminating the occurrence of cable failure.

To achieve the above target, a test on a real feeder (e.g., distribution line) is an unviable solution since the customers downstream will go through a power outage. Therefore, computer simulation of the field tests is developed to study the transient electromagnetic phenomena. Real-time system parameters and measurements are required to prepare system models and perform an exact transient study. This is very useful to identify available voltage surge, determine the equipment insulation coordination, and select protective equipment operating characteristic. However, it is essential to consider the peak over-voltage discrepancy between the frequency-based simulation model results and real-time field measurements.

The power industry has witnessed the evolution of surge arresters from air gap and silicon carbide types to metal oxide varistors (MOV). In extra-high voltage applications, MOV and a breaker with closing resistors are two basic methods to restrict switching surges. In high voltage transmission systems, switching surges are destructive to electrical equipment, so surge arresters are typically installed near large transformers and on line terminals to suppress surges. In medium and low voltage levels, as the penetration of distributed energy resources gets deeper, it is still not clear whether the arresters are a viable solution. One thing is clear: it is not economical to place surge arresters all over the distribution networks due to their vast reaches. Besides surge arresters, other devices used to limit switching overvoltage include pre-insertion resistors and magnetic voltage transformers.

In addition to the device-based method, controlled switching belongs to the second category of overvoltage mitigation methods. The core of controlled switching is statistical switching, where the worst-case scenarios are determined through several dimensions of overvoltage scenarios. Statistical switching has been adopted for decades. Investigated scenarios include switching speed, actual operating capacity, load and line length, etc.

Unlike conventional controlled switching methods that rely on deterministic control, embodiments described herein view controlled switching as a stochastic control. In a deterministic model, the future state is theoretically predictable. Thus, most researchers investigate the statistical switching overvoltage distributions for different switching operations, and then design the control according to the observation. However, in power systems, especially in distribution networks, the switching transient is buffeted by stochasticity. A stochastic model is needed to possess inherent randomness and uncertainty.

Unfortunately, relatively little has been done to develop a stochastic control mechanism that views the complexity of the control task as a Markov decision process (MDP). Since it is hard to assume knowledge or cost function of the overvoltage dynamics, it is desirable to combine the advantages of off-policy control and value function approximation. Meanwhile, given the high-dimensional dynamic complexity of power systems, a deep RL method is redesigned to improve the control performance. Therefore, after the validation, a recloser control method using DQNs is proposed.

Some features of embodiments described herein are summarized below:
Conventional controlled switching methods do not involve observation uncertainty and noise that drives the evolution of the system; therefore, the recloser control problem is formulated by incorporating the temporal sequence reward mechanism into a DQN to mitigate reclosing TOV. Meanwhile, an infeasible-action-space-elimination algorithm is provided through time-variant probability allocation in DQNs.
To overcome the training burden for the proposed RL control method in different applications, a post-learning knowledge transfer method for recloser control is developed to handle complex system operating conditions, save training time, improve the recloser performance, and reduce the required data volume.

Section II provides a discussion of the reclosing impact on underground cables. The proposed recloser control method using RL is elaborated in Section III. Section IV shows numerical results, followed by discussions in Section VI. A computer system for implementing at least some aspects of the present disclosure is described in Section VII.

II. Reclosing Impact on Cables Via PSCAD

As mentioned earlier, one of the reasons for the failure of cable is TOVs. TOV can arise from the supply or from switching inductive loads, harmonic currents, DC feedback, mutual inductance, high-frequency oscillations, large starting currents, and large fluctuating loads. TOV or surges are temporary high magnitude voltage peaks for a short duration of time (e.g., lightning). Switching transients in electrical networks often occurs. Although the voltage magnitude is lower than the lightning surge, the frequency at which it occurs causes aging of cable insulation and eventually breaks down resulting in flashover. To observe the TOVs in computer programs, a 750 MCM-AL cable is used, which is widely implemented in many systems. This section focuses on the modeling of switching and power systems.

A. Switching Modeling

For the switching modeling, statistical breakers in PSCAD are used to account for the physical metal contact and the issue of pole span. Pole span is the time span between the closing instant of the first and the last pole. The single-pole operation of three-phase breaker is applied to incorporate the angle difference in the operation of different poles because of the mechanical inconsistencies. The resulting TOVs upon 100 simulations of different sets of circuit breaker closing times with a standard deviation of 4 in the half interval are shown in Table I. This table brings some flavors on how the pole span contributes to the maximum TOVs. One can refer to Section IV-A for the system parameters.

TABLE I
Comparison Under Three Types of Pole Spans

| Pole span (ms) | Highest TOV (pu) | Avg. TOV (pu) |
|---|---|---|
| 0 | 1.55 | 1.55 |
| 0.24 | 1.58 | 1.52 |
| 3.7 | 1.58 | 1.51 |

When the switching occurs at other angles, different TOVs are obtained. Although this does not demonstrate all the cases with higher TOVs, it shows that the optimal controlled switching time is crucial to TOV mitigation under the current switching modeling. It is noteworthy that the limitation of the adopted switch modeling is imperfect, the details of which can be found in Section VI. Meanwhile, it is evident that over-voltages frequently occur on cables; therefore, it is imperative to provide a solution that lowers the probability of cable failure.

B. Power System Modeling

Firstly, two different line models, namely, distributed line model and frequency-dependent π model, are employed to capture different aspects of cable characteristics.

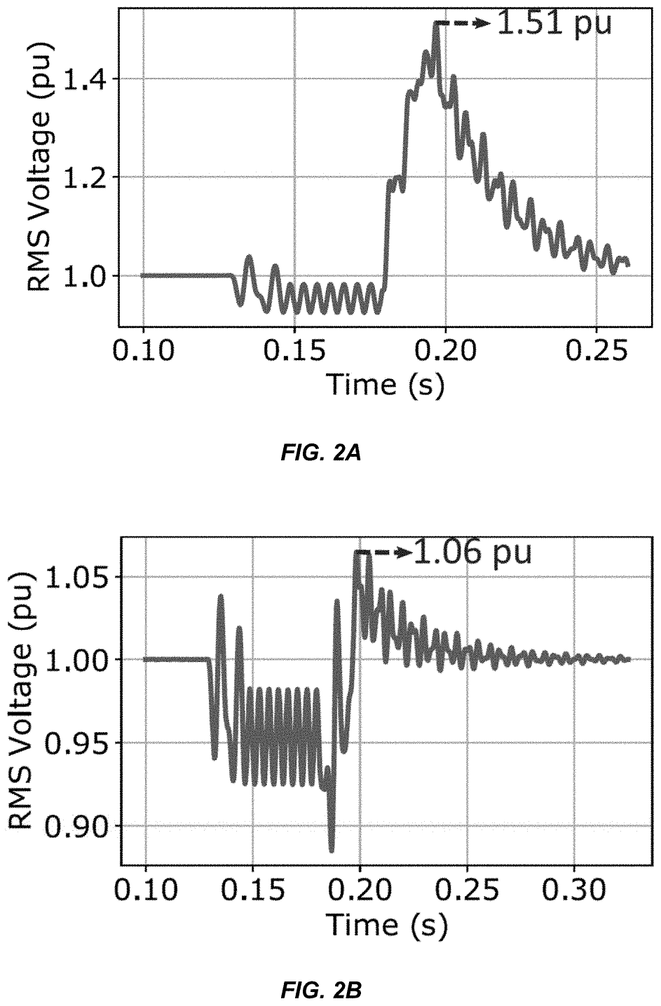

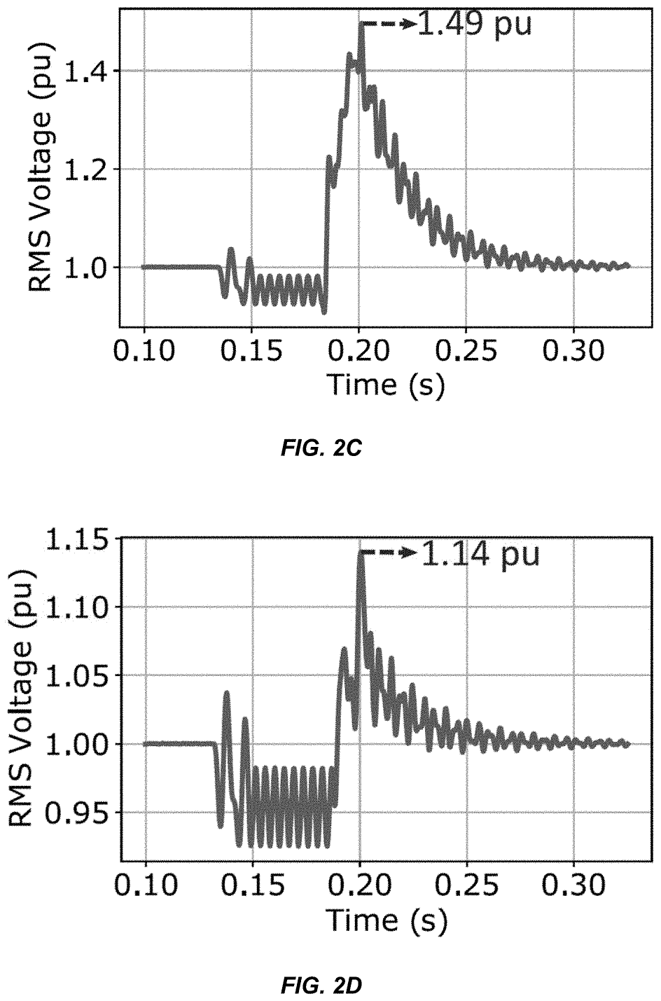

FIG. 2A is a graphical representation of an example of the TOV waveform for a distributed line model plotted using PSCAD when the reclosing angle is set at 0°. FIG. 2B is a graphical representation of the TOV waveform of FIG. 2A when the reclosing angle is set at 45°. FIG. 2C is a graphical representation of the TOV waveform of FIG. 2A when the reclosing angle is set at 90°. FIG. 2D is a graphical representation of the TOV waveform of FIG. 2A when the reclosing angle is set at 180°. The recloser opens at t=0.12 seconds (s) and closes at t=0.17 s. Tests are under lagging load condition at a 12 kilovolts (kV) feeder connecting with a 2.5 miles long cable using a distributed line model.

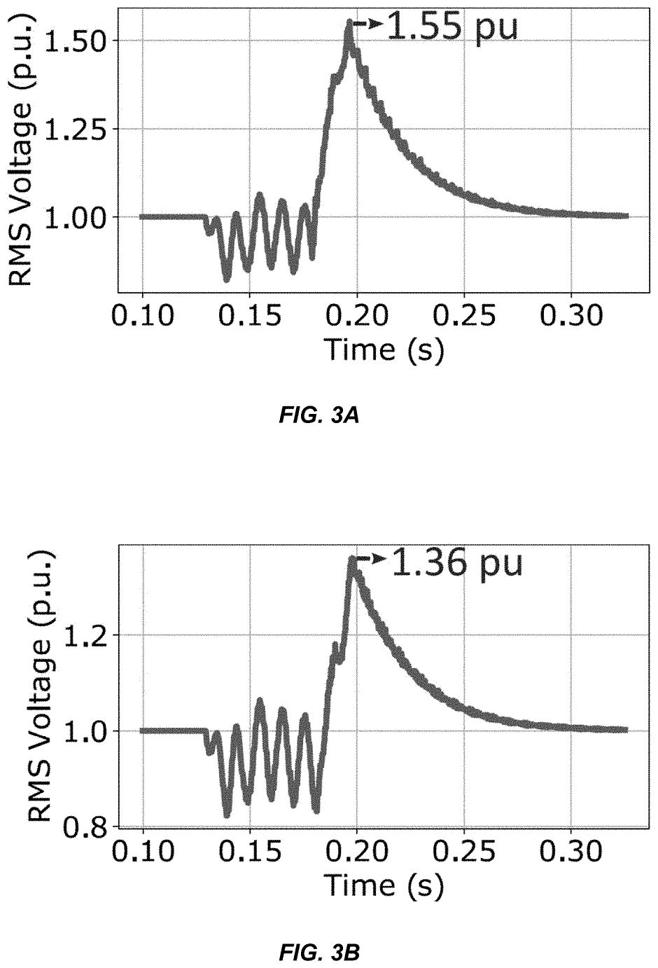

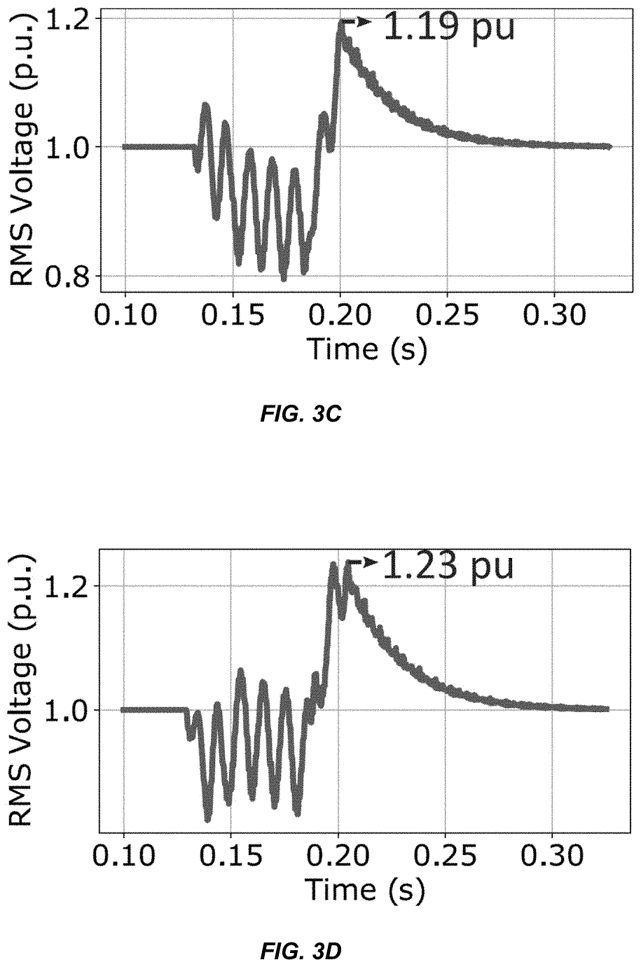

FIG. 3A is a graphical representation of an example of the TOV waveform for a frequency-dependent π model plotted using PSCAD when the reclosing angle is set at 0°. FIG. 3B is a graphical representation of the TOV waveform of FIG. 3A when the reclosing angle is set at 45°. FIG. 3C is a graphical representation of the TOV waveform of FIG. 3A when the reclosing angle is set at 90°. FIG. 3D is a graphical representation of the TOV waveform of FIG. 3A when the reclosing angle is set at 180°. The recloser opens at t=0.12 seconds (s) and closes at t=0.17 s. Tests are under lagging load condition at a 12 kV feeder connecting with a 2.5 miles long cable using a distributed line model.

With reference to FIGS. 2A-2D and 3A-3D, at the end of the cable, a capacitor bank and transformers are connected to represent the reality, which explains the occurrence of the resonance effect during recloser dead time. In the case of a distributed line model, a TOV of 1.51 per-unit (pu) is observed when switching at zero degree of the source voltage. However, a TOV of 1.55 pu is observed when a frequency-dependent π model is used. In the majority of the cases, TOVs are higher with a π model because resistance, inductance and capacitance of the line are considered together. Secondly, a detailed three-phase voltage source model is selected from the PSCAD library. The associated parameters, in particular the source impedance, are adopted from realistic distribution feeders.

III. RL-Based Recloser Control Method

It is important to select an RL method that is suitable for the particular problem under study. In general, RL is classified into model-based (MB) and model-free (MF). In MB RL, the classical World model is chosen as an example. Since it is MB, an environmental model is needed during learning. However, given the complexity of the TOV problem under study, it is hard to construct an internal model of the transitions and immediate outcomes for recloser control. For this reason, some embodiments do not use MB RL. In MF RL algorithms, the agent relies on trial-and-error experience to reach the optimal policy. The typical methods include policy optimization and Q-learning. Under the policy optimization approach, the popular policy gradient (PG) is selected as a comparison.

In contrast, for Q-learning methods the basic version and the advanced version DQN are chosen. Please note that this paper utilizes DQN method for RL control. The main advantage of DQN over PG is that it involves discrete action space, while PG is for continuous action spaces. it is desirable to reduce the action space. However, PG method will consider 0, 1 and anything in between, whereas a breaker can have precisely two discrete actions (Off and On). Therefore, owing to the discrete nature of the action space involved in Q-learning-based RL, it is perhaps the best choice to reduce the computational burden. For the selection between Q-learning and DQN, certain embodiments use DQN due to its powerful value function approximation capability in multiple power system scenarios. The above comparison of selecting the RL methods is summarized in Table II, where bold and underlined text indicates the main reason for why this method has not been selected.

TABLE II
Comparison of Four Reinforcement Learning Approaches

| | | Policy | Q- | |
|---|---|---|---|---|
| Item | World model | gradient | learning | DQN |
| Model-based (MB) | MB | MF | MF | MF |
| of model-free (MF)? | | | | |
| Need environmental | Yes | No | No | No |
| model? | | | | |
| Based on value | No | No | Yes | Yes |
| function? | | | | |
| Value function | No | No | No | Yes |
| approximation? | | | | |
| Action Space | Continuous/Discrete | Continuous | Discrete | Discrete |

The remaining part of this section starts with the impetus of choosing the DQN algorithm, which is capable of dealing with the continuous status space of the recloser observation. To control the reclosers, the design of temporal sequence reward mechanism, infeasible action space elimination algorithm, and the post-learning knowledge transfer method are elaborated.

A. The Deep Q-Network (DQN) for Better Value Approximation

The task of TOV mitigation requires a model-free control algorithm that finds an optimal strategy for solving a dynamical control problem. Obviously, RL is a suitable solution. Among various types of RL algorithms, the off-policy control where the agent usually uses a greedy policy to select actions can be incorporated with the action value estimation design. Therefore, Q-learning is chosen to satisfy this requirement. Based on the complexity of the electric grids, the value-based DQN method needs to involve intensive use of simulation for the parametric approximation. To enable self-learning of the recloser control, an actor-critic system is adopted to estimate the rewards. The critic in this system evaluates the value function, and the actor is the algorithm that improves the obtained value. DQN agents use the following training algorithm, in which they update their critic model at each time step. First, the critic Q(s, a) needs to be initialized with random parameter values θ_{Q}, and initialize the target critic with the target update smoothing method. Then, at each time step:
1) With probability ε, select a random action A. Otherwise, select the action that maximizes the critic value function:

$$A = {argmax}_{A} Q ( S , A \vert {θ}_{Q} ) \qquad Equation 1$$

It makes sure the off-policy method always follows the greedy policy—the best action value estimations.
2) Execute action A, then calculate the reward R and the next state S′. If there are associated TOVs, they will be measured in this step, and the reward is calculated.
3) Store the experience (S, A, R, S′) in the experience buffer. This technique smooths the training distribution over many past behaviors.
4) Randomly sample M experiences (Sᵢ, Aᵢ, Rᵢ, Sᵢ′) from the experience buffer. The M sampled dataset is called the random mini batch. If Sᵢ′ is a terminal state, set the value function target yᵢ to Rᵢ. Otherwise set it to:

$${y}_{i} = {R}_{i} + γ {max}_{{A}^{′}} {Q}^{′} ( {S}_{i}^{′} , {A}_{i}^{′} \vert {θ}_{{Q}^{′}} ) \qquad Equation 2$$

where γ is the discount factor, and Q′ is the value for the next state. In such a way, the current state that the recloser measures is represented in a form that the RL agent can interpret.
5) Update the critic parameters by one-step minimization of the loss L across all sampled experiences:

$$L = \frac{1}{M} {\sum }_{i = 1}^{M} {( {y}_{i} - Q ( {S}_{i} , {A}_{i} \vert {θ}_{Q} ) )}^{2} \qquad Equation 3$$

Thereby, the parameter θ_{Q} for value approximation is calculated.
6) Update the target critic using the target smoothing update methods (r is the smoothing factor):

θ_{Q′}=τθ_{Q}+(1−τ)θ_{Q′} Equation 4

B. Temporal Sequence Reward to Guarantee Learning Quality

To develop a DQN to mitigate TOVs, its state design is first considered. For each phase p∈{A, B, C}, there are voltage and current measurements from the bus located downstream of the breaker under study. Similar to a conventional recloser, the magnitudes of voltage |Vₚ| and current |Iₚ| along with the voltage phase angle θ_{V}_{ₚ} and current phase angle θ_{I}_{ₚ} of the measurements are selected for defining a 4-dimensional state space s of the system:

s=[|Vₚ|,θ_{V}_{ₚ},|Iₚ|,θ_{I}_{ₚ}]^{T} Equation 5

After defining the state, the action space of the controlling system is defined that suits the system and can deliver the best results. Practically, the opening of the recloser is usually triggered by faults and subsequent to the series of pre-defined sequence. Electronically controlled reclosers are usually set to trip two to three times, using a combination of fast and slow time-current curves. It is assumed that the opening of reclosers is taken care of by the conventional fault detection method and the pre-defined sequence. Thus, due to the simplicity of the control task, a binary action space a∈{0,1} is selected. Here, 0 indicates that no reclosing is required, whereas 1 indicates there is a reclosing action. It is necessary to remind the reader that there is an essential dimension of the action—time, which is the key to a successful reclosing.

Since the RL control agent learns through its special “feedback”-reward to improve its performance, it is important to design the reward mechanism that captures the key task sequence and maximizes its accumulative reward from the initial state to the terminal state (one episode). Therefore, a reward function is designed that makes the agent learn the optimal time to reclose in the continuous state space. To achieve that, the reward function should evaluate the voltage deviation upon reclosing and consider the reclosing dead time. Consequently, for each time step t and the jth agent:

R_{tovi,t}^{j}=α−β·B_{RisingEdge}·[|V_{p,t}|−V_{ref,t}]₃₀−ζ·[t_{S}_{_{R}}₌₀−t_{TH}]₊ Equation 6

where α, β, and ζ are adjustable scaling factors. Their values are adjustable in a specific case. The value of a determines the highest attainable reward. B_{RisingEdge} is the signal bit that becomes high only when it captures the rising edge of the recloser j's status (changes from open (0) to close (1)). While t_{S}_{_{R}}₌₀ is the time duration that recloser remains open, and t_{TH} is the allowable recloser opening time threshold that is usually the recloser dead time. The mathematical operator [·]₊ keeps the value inside the bracket unchanged when it is non-negative, and output zero when it is negative. β and ζ denote the extent of punishment on TOV and reclosing delay. Mathematically, R_{tovi,t}^{j} is proportional to the voltage deviation at time t from the customer-defined reference voltage, V_{ref}. The task sequencing can be achieved by enabling the model to learn on the number of distinct action sequences.

Furthermore, it is beneficial to have a reward that evaluates the overall performance at the end of the episode. Thereby, the end of the episode reward Rₑₑ^{j} is designed:

Rₑₑ^{j}=−θ·[N_{Reclose}−N_{pre-defined}]₊ Equation 7

where θ is a scaling factor, N_{Reclose} and N_{pre-defined} are the number of reclosing over one episode and the pre-defined number of tripping programmed in the recloser. Thus, the reward function in one episode becomes:

R^{j}=Σₜ₌₁^{T}R_{tovi,t}^{j}−Rₑₑ^{j} Equation 8

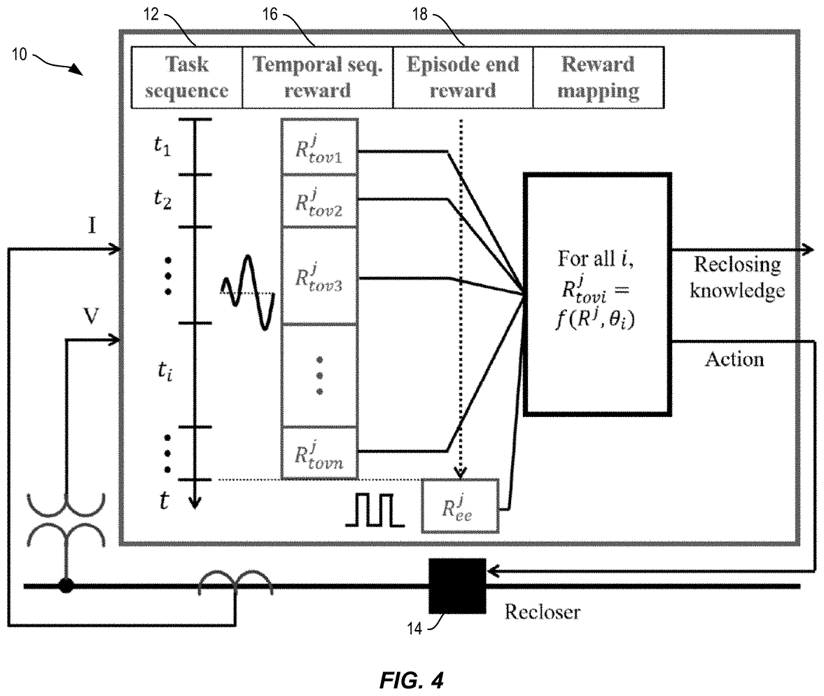

FIG. 4 is a schematic diagram of an exemplary recloser controller 10 illustrating its reward design. Given the temporal characteristics of the reclosing task, a time horizon for the task sequence 12 is illustrated in the left of the recloser controller 10. The recloser controller 10 takes voltage V and current I as inputs, and outputs reclosing knowledge and action (e.g., to cause a recloser 14 to reclose). The recloser controller 10 may be coupled to the recloser 14 (e.g., at a remote location or adjacent the recloser 14), or it may be embedded in the recloser 14. Following the time series t₁, t₂, . . . , tₙ, the reward comprises two parts, the instantaneous temporal sequence reward 16 (R_{tovi,t}^{j}) and the reward at the end of the episode 18 (Rₑₑ^{j}). In fact, the second term in Equation 6 pushes the model to learn the best time to reclose; whereas the third term in Equation 6 helps the agent avoid not closing at all. To help the reader better understand the outcome of the time sequence mechanism, it is assumed that the agent has learned “well” enough and made sure (a) the resulting voltage after reclosing is equal to V_{ref}, (b) no delayed tripping is observed, and (c) the number of reclosing matches the pre-defined value.

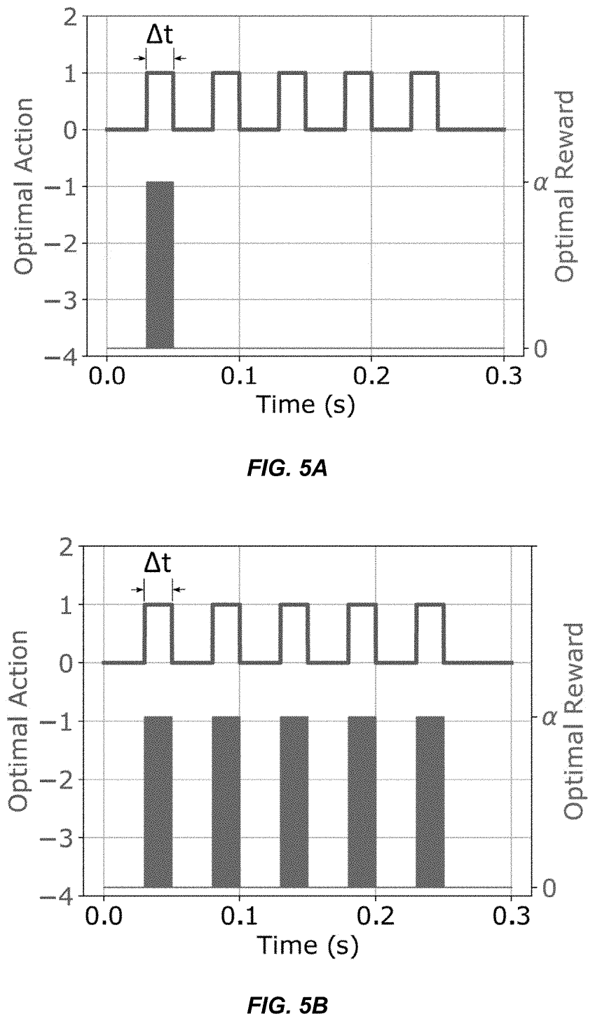

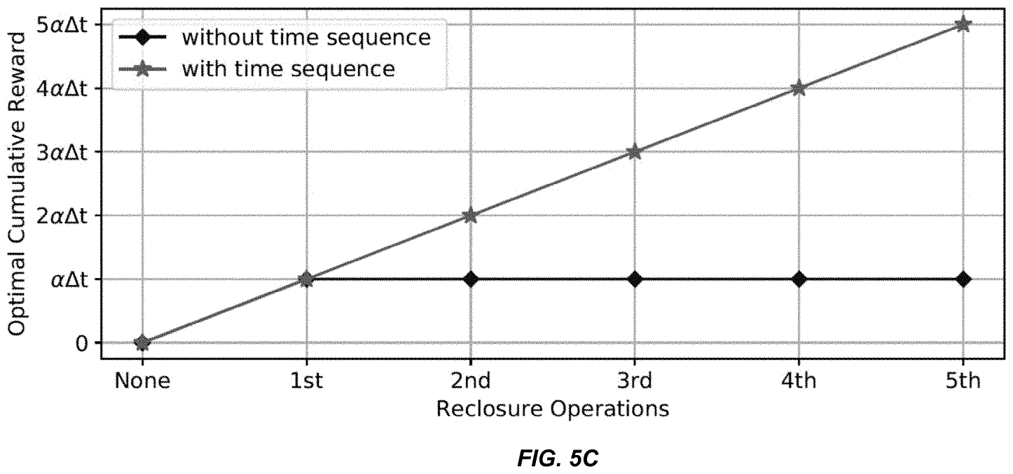

FIG. 5A is a graphical representation of action-reward pairs without time sequence-based reward design for five breaker operations. FIG. 5B is a graphical representation of action-reward pairs with time sequence-based reward design for five breaker operations. FIG. 5C is a graphical representation of the cumulative rewards for the designs of FIGS. 5A and 5B. These figures illustrate the reward with and without the time sequence design. Over the five recloser operations, the time sequence design reward captures all five reward increasing opportunities, while the one without this design can hardly do it. Since Equation 6 indicates that optimal reward will be a which may last for Δt time, the discounted reward for each reclosure operation (reclose, wait for Δt and open again) will be bounded at αΔt when time sequences are not considered. Whereas a time sequence-based reward can capture the incremental reward with increasing reclosure operations, as shown in FIG. 5C.

C. Infeasible Action Space Elimination for Fast Learning

With the time dimension considered, the action space is immense. To have a working algorithm, it is necessary to remove most of the infeasible action space to make sure of the performance and efficiency. A generalized DQN algorithm usually solves problems or games that do not contain the time dimension. However, in this particular issue, after investigating the DQN algorithm in Section III-A, the time dimension is introduced to embed the physical law into the algorithm—eliminating the physically infeasible region and enhancing the exploitation in the physically feasible region. It makes sure that the probability of action, according to the time sequence, can be pushed up from a state if this action is better than the value of what should occur from that state. The probability ε in Section III-A is now redefined as follows:

$${ɛ}_{t} = \{ \begin{matrix}{ɛ}_{0} ( t ) & t = ( t {r}_{i} , {tr}_{i} + n / f ) \\ 0 & otherwise\end{matrix} \qquad Equation 9$$

where ε₀(t) denotes the base exploration rate, which is a function of time. trᵢ denotes the pre-defined opening time of sequences. f is the grid frequency and n/f confines the exploration within n cycles. The agent's timer is on as long as a fault is detected.

Traditionally, the agent explores the action space from the first time-step to the last one. Whereas this is not necessary most of the time if the agent wants to achieve a reduced resulting TOV. For instance, the actions taken before the fault or in between two pre-defined trips are dispensable. Therefore, the notion of restricting the exploration to the time sequences where the action is required is conceived. Such a prior domain knowledge can help to gain higher rewards even in the initial few episodes. Hence, the temporal reward design is aligned with the temporal action likelihood. Assuming P(aₜ) as the prior distribution for the possible actions

$${P}^{*} ( {a}_{c} ) = \{ \begin{matrix}P ( {a}_{t} ) & t ∈ applicabale time sequences \\ 0 & otherwise\end{matrix} \qquad Equation 10$$

where P*(aₜ) is the probability distribution of taking possible actions for the appropriate time sequences where exploration is needed. Such a formulation incorporates physically feasible interpretation into the model's MDP probability change. For a breaker control problem, the probabilities of having specific control actions may impact the performance mainly by restricting the exploration to a suitable temporal region and selecting appropriate probabilities of on or off actions for the breaker. So, an extensive analysis can be performed to show what probability distributions are reasonable. This begins by selecting off and on status completely randomly, i.e., both with 0.5 probability. Then the probability of occurrence of status on continues to increase since the breaker is expected to remain on for a greater number of steps once it is reclosed. The pseudo-code is shown in Algorithm 1.

Algorithm 1; Deep Q-learning for Recloser Control Agent

| | |
|---|---|
| 1 | Initialize experience buffer [symbol] to capacity N; |
| 2 | Initialize action-value function Q with random weights; |
| 3 | Initialize P(aₜ) with prior knowledge; |
| 4 | for episode = 1, E do |
| 5 | \|Initialize sequence s₁ = {x₁} and pre-processed sequence ϕ₁ = ϕ (s₁); |
| 6 | \|for t = 1, T do |
| 7 | \| \| $With probability {ɛ}_{t} , set {P}^{*} ( {a}_{t} ) = \{ \begin{matrix}P ( {a}_{t} ) , & t ∈ applicable time sequences \\ 0 , & Otherwise\end{matrix}$ |
| 8 | \| \|select aₜ with probability P* (aₜ); otherwise select aₜ = maxₐ Q* (ϕ (sₜ), a; θ); |
| 9 | \| \|Execute action aₜ in emulator and observe reward rₜ and image xₜ₊₁; |
| 10 | \| \|Set sₜ₊₁ = sₜ, aₜ, xₜ₊₁ and observe reward rₜ and image xₜ₊₁; |
| 11 | \| \|Store transition (ϕₜ, aₜ, rₜ, ϕₜ₊₁) in [symbol] ; |
| 12 | \| \|Sample random minibatch (with size M) of transitions (ϕⱼ, aⱼ, rⱼ, ϕⱼ₊₁) from [symbol] ; |
| 13 | \| \| $Set {y}_{j} = \{ \begin{matrix}{r}_{j} , & for terminal {ϕ}_{j + 1} \\ {r}_{j} + γ {max}_{{a}^{t}} Q ( {ϕ}_{j + 1} , {a}^{t} ; θ ) , & for non \text{-} terminal {ϕ}_{j + 1}\end{matrix}$ |
| 14 | \| \|Perform a gradient descent step on (yⱼ − Q(ϕⱼ, aⱼ; θ))² based on (3) |
| 15 | \|end |
| 16 | end |

D. Post-Learning Knowledge Transfer

The transferability of RL and other machine learning control methods is sometimes questioned by researchers, since, unlike deterministic control, machine learning control needs to tune its parameters based on case-specific training. This is not efficient. To overcome this issue, an adopted approach involves fitting a polynomial line R_{f}∈ [symbol] ⁿ 2 Rn, where n is the degree of the polynomial, with reward parameters using an evaluation reward R(Sᵢ, Aᵢ). The degree of the polynomial is a hyperparameter which affects the speed of training:

R_{f}=θ₀+θ₁R(S₁,A₁)+θ₂R²(S₂,A₂)+ . . . +θₙRⁿ(Sₙ,Aₙ) Equation 11

where θᵢ is the coefficient of the ith polynomial term. Such a polynomial function can be fitted through least square-based regression.

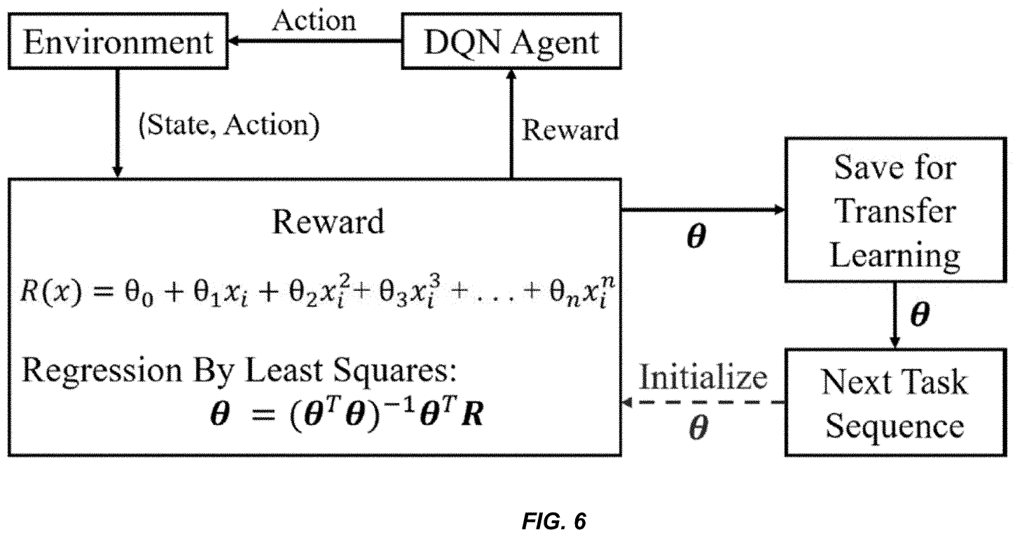

FIG. 6 is a schematic diagram of an exemplary approach to learning a reward function along with an agent by fitting the reward to a polynomial function. The parameters of the reward function are saved for the transfer learning process whenever there is a need for a new task sequence to be learned. Such a process enhances the adaptability of the model and is not restricted to only a particular environmental setting.

IV. Numerical Results

A. Benchmark System

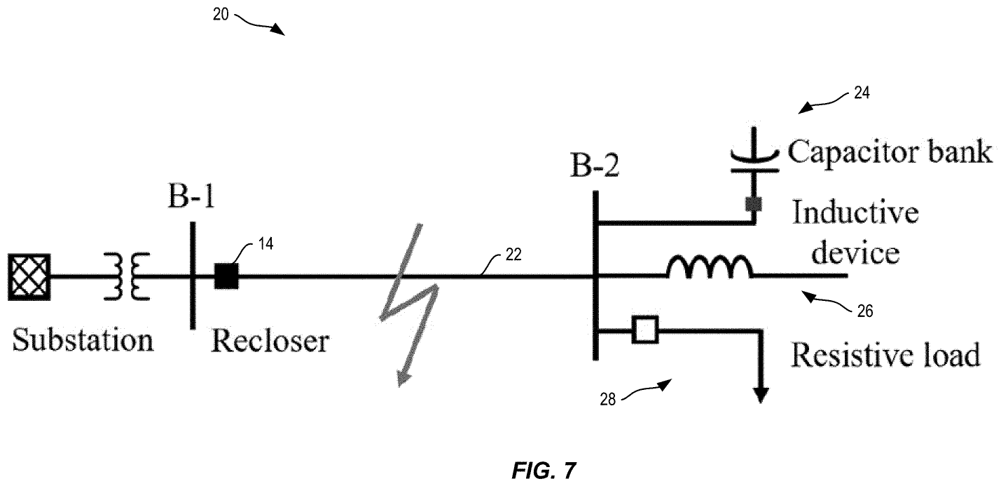

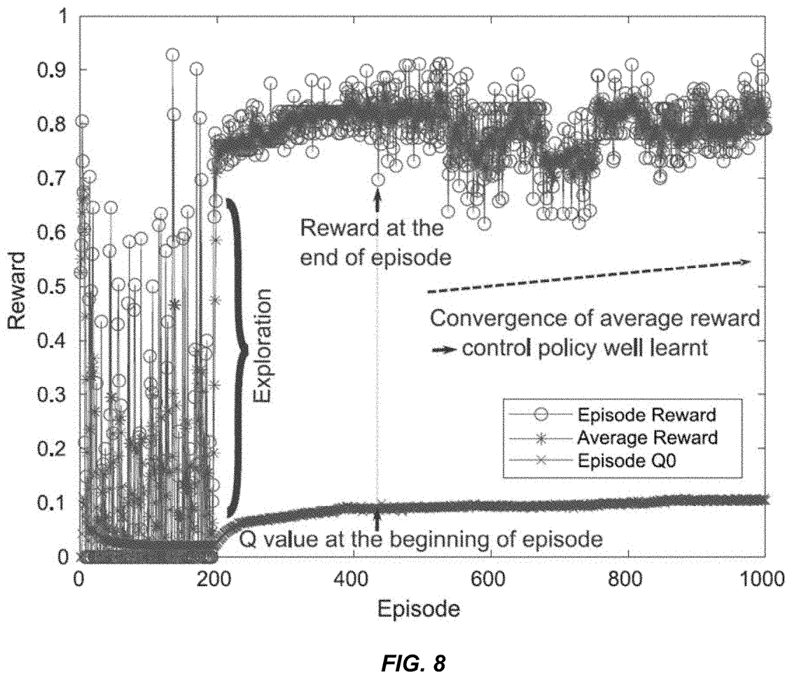

FIG. 7 is a schematic diagram of an exemplary benchmark power distribution system 20 used for evaluating embodiments described herein. The proposed method is extensively tested in various systems. This section presents the results for the generalized benchmark power distribution system 20 of FIG. 7. This system is a 12 kV, 100 megavolt ampere (MVA) feeder with a 2.5-mile-long underground cable 22, with a capacitor bank 24 and an 8-megawatt (MW) load at the feeder end. Meanwhile, the feeder circuit has 2 types of cable 22: (1) 750 Copper, XLPE, 15 kV 100% insulated, 26—#22 wire shield, jacketed, and (2) 750 Aluminum, XLPE, 15 kV 100% insulated, 12—#12 concentric neutral, jacketed. The feeder duct bank uses 3-inch PVC conduits arranged horizontally, concrete encased, burial depth 48 inches. Tests include different load conditions, source parameter change, and frequency oscillation, etc. The loads can be capacitive (C), inductive (L), resistive (R), or any of their combination. The cable 22 is represented as (1) a distributed line model and (2) a frequency-dependent π model using realistic underground cable parameters, the data of which is shown in Tables III and IV.

TABLE III
Source and Line Parameters

| Source Parameters | | Line Parameters | |
|---|---|---|---|
| Voltage (kV) | 12 | Length (mi) | 2.5 |
| Capacity (MVA) | 100 | Conductor | 750 MCM-AL |
| R (Ω) | 0.2326 | R (Ω) | 0.3163 |
| L (H) | 0.007 | L (H) | 0.0026 |
| | | C (pF) | 112.4 |

TABLE IV
Load Parameters

| | |
|---|---|
| C (μ) | 0.05 |
| L (H) | 0.08 |
| R (Ω) | 8 |

With the benchmark model, the impact of different load types on TOVs is first evaluated. As shown in Table V, the load types of C and LC are two significant causes of cable TOVs. They are, in reality, the capacitor bank 24 and the inductive loads 26, including transformer connected to the cable 22. With a decreased L or increased C, the maximum TOVs tend to increase, since the load becomes more and more capacitive in nature. Furthermore, for only load type C, the highest maximum TOVs are observed, because upon reclosure the voltages are held at high values by the charged capacitor and there is no alternate route to discharge. The results also indicate that a resistive load 28 serves as the drain of the trapped charge in the cable; therefore, the TOVs are hardly observed.

TABLE V
Impact of Different Load Types on TOVs

| Load Type | | | | Underground Line |
|---|---|---|---|---|
| Resistive | Inductive | Capacitive | TOV | Max. Value of TOV (pu) |
| On | On | On | x | — |
| On | Off | On | x | — |
| Off | On | On | ✓ | 1.5 |
| Off | Off | On | ✓ | 2.2 |
| Off | On | Off | x | — |
| On | On | Off | x | — |
| On | Off | Off | x | — |

Additionally, the TOVs have large deviations when switching off the loads due to possible restrikes. Therefore, this can also be one of the reasons for causing detrimental TOVs. To study such a phenomenon of load switching due to restrikes and develop a deeper insight into the matter, the switching scenarios are expanded with rigorous experimentation to identify the highest TOV values upon multiple restrikes. Results are presented in Table VI. This analysis shows that there is a high TOV when the load is shed without losing capacitor banks. The controller can also be designed to mitigate such TOVs.

TABLE VI
Impact of Load Switching on TOVs

| | | |
|---|---|---|
| Before Switching | After Switching | TOV |

| R | L | C | R | L | C | (pu) |
|---|---|---|---|---|---|---|
| On | On | On | Off | Off | On | 1.54 |
| On | On | On | Off | On | On | 1.23 |
| On | On | On | Off | On | Off | 1.49 |
| On | On | On | Off | Off | On | 1.20 |
| On | On | On | On | Off | Off | 1.05 |

B. Overall Learning Curve by Using the Temporal Sequence Reward Mechanism and Hyper-Parameter Selection

FIG. 8 is a graphical representation of a learning curve that shows the individual episode reward, average reward, and Q value at the beginning of each episode named Episode Q₀. This learning curve is achieved with the proposed temporal sequence reward mechanism and deep Q-learning algorithm in Section III-B and III-C. By looking at the average reward, it shows that the agent has many attempts to explore the optimal control action that accumulates the rewards. Some of the episode rewards are high, and some are low. A breakthrough is not realized until the episode number turns 200. After that, the agent continues refining its policy to improve its learning. Although the average reward gets a bit low at episode 550-750, the agent manages to get rid of some low-performance policies and fulfill a higher reward after episode 750. Next, a hyperparameter selection approach that achieves improved results is explained.

1. Discounting Factor (γ)

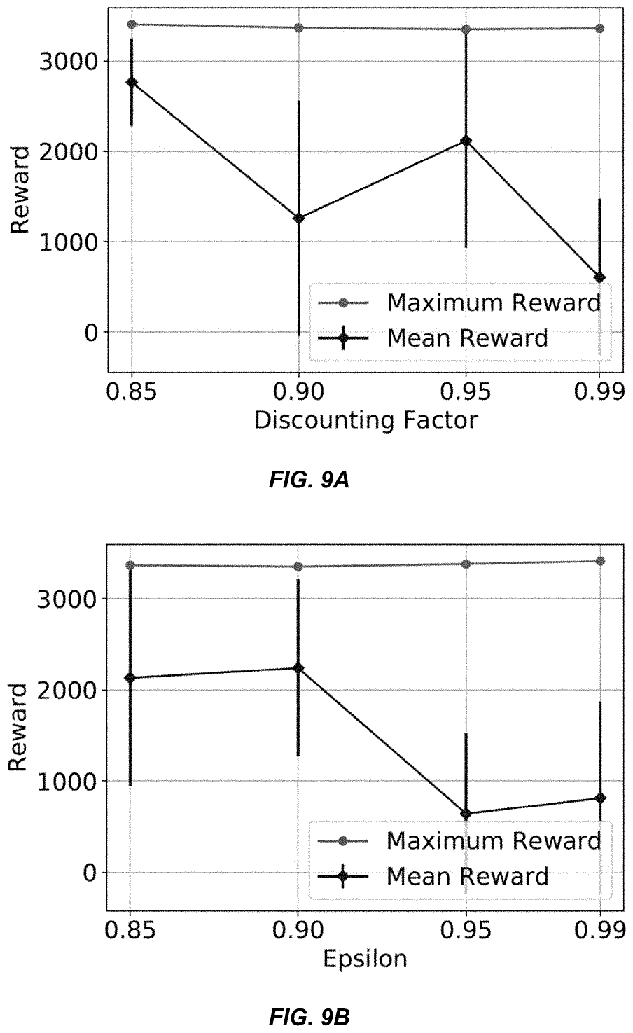

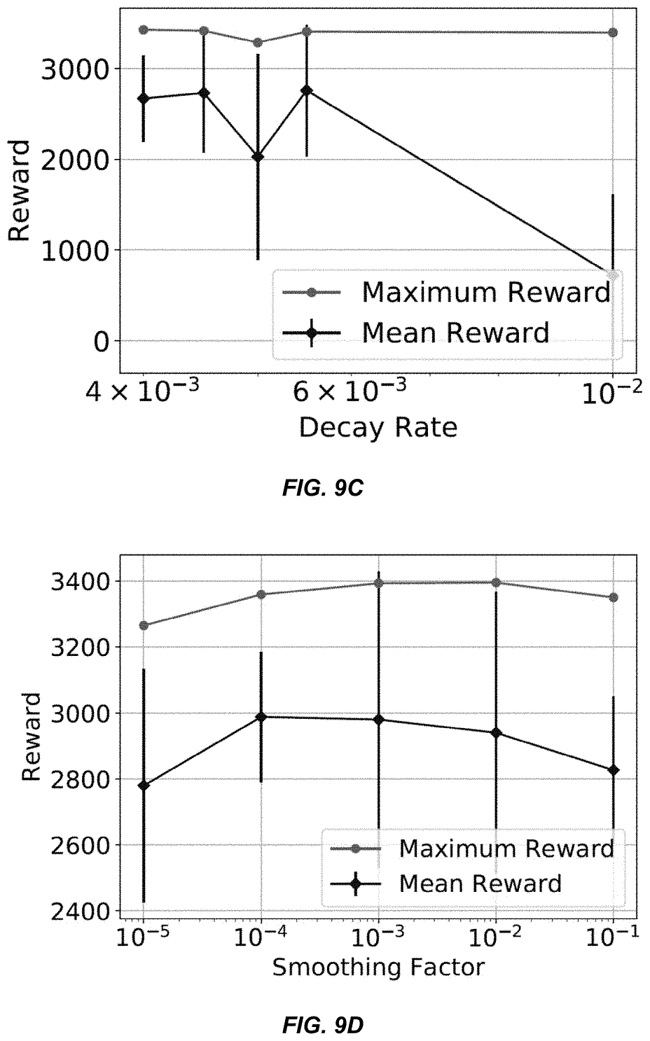

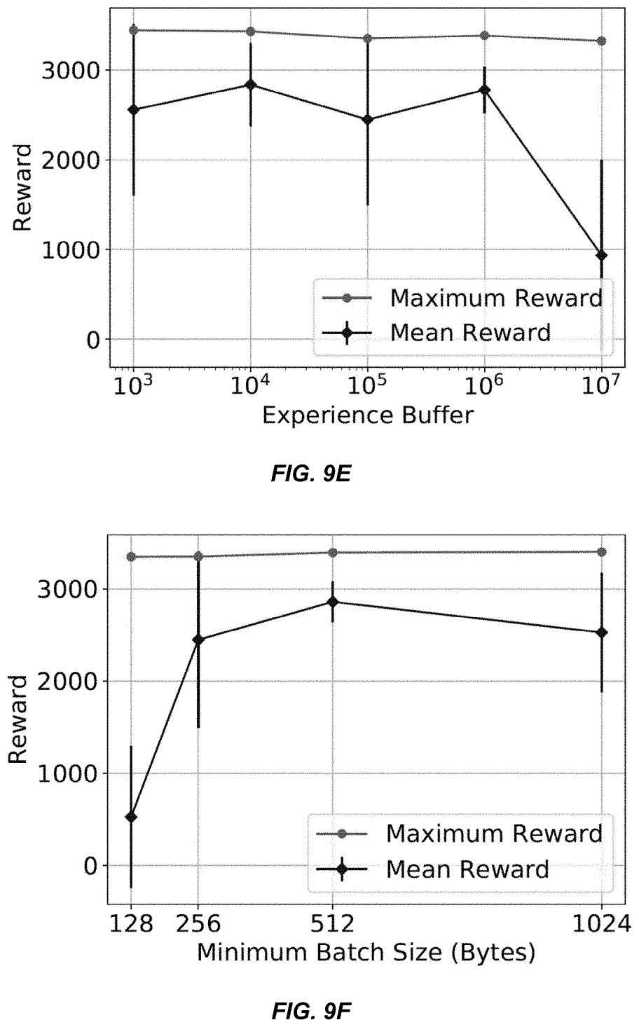

FIG. 9A is a graphical representation of the effect of the discounting factor γ on the breaker controlling reward. Intuitively, a value that gives the highest bounded reward will be a fair discounting factor. But there is a need for enough exploration as well; therefore, a discounting factor with an intensive exploration of the space while achieving a high reward would be preferable. A discounting factor of 0.95 is applied in this study so that a fair compromise is achieved between the mean value of reward and the exploration that can be shown as the standard deviation of the discounted reward values for all episodes.

2. Epsilon (ε)

FIG. 9B is a graphical representation of the effect of the E value on the breaker controlling reward. The exploration and exploitation are controlled by the E value in the epsilon-greedy algorithm. By progressively increasing the epsilon from 0.85 to 0.99, 0.90 is chosen as its optimal value since it shows the maximum reward achieved. It is noteworthy that increasing the epsilon further increases the likelihood of reaching a local minimum. That is why an evaluated embodiment does not adopt a higher E that has a higher maximum reward.

3. Decay Rate

FIG. 9C is a graphical representation of the effect of the decay rate on the breaker controlling reward. This figure indicates the behavior of reward by increasing decay rate value from 0.004 to 0.01. The optimal decay rate value is concluded to be 0.005, because the mean reward is highest at that point without compromising much on the exploration. However, most exploration is shown as the standard deviation at 0.0045, but it never achieves the maximum possible reward, so its mean is very low as compared to that of the mean at the prescribed decay rate of 0.005.

4. Smoothing Factor (τ)

FIG. 9D is a graphical representation of the effect of the smoothing factor τ on the breaker controlling reward. Such a factor varies with respect to the reward value. The value of mean reward is high when a smoothing factor of 0.01 is selected, and the standard deviation is maintained relatively high too. Both considerations are key to selecting a parameter since the aim is to maximize the reward expectation while providing enough exploration space.

5. Experience Buffer ( [symbol] ) with Capacity N

FIG. 9E is a graphical representation of the effect of the experience buffer [symbol] on the breaker controlling reward. Since experience replay is used to predict the value function, the size of the experience buffer needs to be decided to converge the learning model to achieve high rewards. The evaluated embodiment uses 100,000 as the optimal value of experience buffer since it has a significant standard deviation to allow random exploration and achieve high reward simultaneously.

6. Minimum Batch Size (M)

FIG. 9F is a graphical representation of the effect of the minimum batch size M on the breaker controlling reward. The minimum batch size determines the dataset to be fed to the neural networks for their learning. FIG. 9F indicates that the maximum exploration has been achieved when the size is 256 bytes. However, 512 bytes deliver a high mean reward, but the exploration is insufficient. Additionally, 1,024 bytes result in fairly reasonable exploration with high mean but will consume too much memory, which increases the computational time and is undesirable.

The proposed learning agent is trained for different X/R ratios of the source, which impacts the cumulative reward obtained by the learning agent. The X/R ratio is varied from 8 to 20 with a step size of 4, keeping into consideration the realistic X/R ratios in a distribution network. The maximum peak TOV can reach up to 2.2 pu when the X/R ratio equals to 12. The results of mean, maximum, and standard deviation (Std.) of the reward vectors upon complete training for each sample are tabulated in Table VII. The results indicate a high mean and maximum reward in all cases. Interestingly, an X/R ratio of around 12 for the system under discourse gives the highest mean and maximum reward values with the least standard deviation.

TABLE VII
Effect of Change of X/R Ratio of the Source on Reward of the Agent

| Source X/R Ratio | Mean Reward | Maximum Reward | Std. Reward |
|---|---|---|---|
| 8 | 1745 | 3156 | 1164 |
| 12 | 2548 | 3311 | 669 |
| 16 | 1790 | 3244 | 1254 |
| 20 | 2456 | 3201 | 770 |

C. Fast Learning Curve with Infeasible Region Eliminated

It is proposed to eliminate the region where a particular action is infeasible from the exploration by implementing a carefully designed varying probability approach.

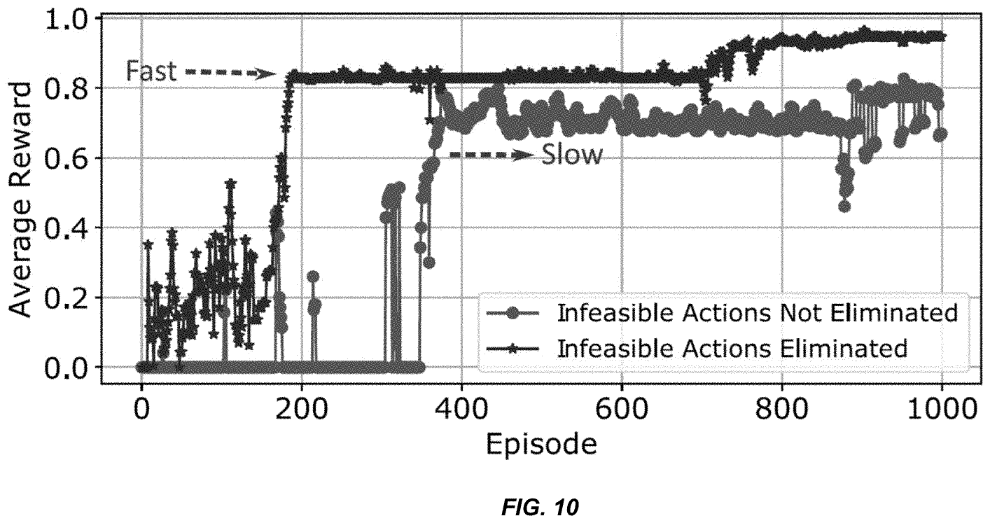

FIG. 10 is a graphical representation of a learning curve comparison with and without the infeasible action eliminated. This provides validation of that concept by showing that a faster convergence is ensured by embedding domain knowledge in the exploration process. When the infeasible actions are not eliminated, it takes about 200 more episodes for the agent to realize a significant reward increase. Interestingly, the stable region in the middle of the learning curve without eliminated infeasible actions is even lower than the one with eliminated infeasible actions. The former takes 900 episodes to achieve the latter's reward that takes less than 200 episodes. At around the 700th episode, the average award is boosted again with the proposed infeasible region elimination method.

D. Efficient Knowledge Transfer for Method Generalization

Some embodiments aim to boost the learning process further to make the proposed method adaptive and general. There are multiple time sequences need to be learned by the model. Table VIII illustrates that a flat start model without knowledge transfer requires many numbers of episodes to gain an average reward higher than 0.7. To ameliorate such a situation, the knowledge transfer method described herein helps to reduce the number of episodes, since it has the capability of retaining the reward information from the past time sequences. With transfer learning, 261 episodes are required to gain a reward above the normalized reward of 0.7, as compared to 394 episodes with the approach of flat start, when the model is learning on the first two time sequences. For the first three time sequences, 289 episodes are required in comparison to 682 episodes. Hence, such a method of transferring reward knowledge supports the training time reduction significantly. Moreover, the generalization of reward parameters also helps in systems with other configurations to enable the reward knowledge transfer.

TABLE VIII
Effect of Transferring Post Learning Knowledge

| | # of episodes taken to reach average reward of 0.7 | | |
|---|---|---|---|
| Comparison | 1 time seq. | 2 time seq. | 3 time seq. |
| Flat Start | 237 | 394 | 682 |
| Transfer Learning | 212 | 261 | 289 |

V. Performance Comparison with Other Methods

The temporal sequence based RL technique provides a framework to learn optimal breaker reclosure time that helps ameliorate the TOV. There have been efforts in the past to accomplish such a task. One traditional method is to reclose whenever the source side voltage crosses zero value. This zero-crossing method is easy to implement in a recloser but not effective. Therefore, the proposed method is compared with another controlled switching scheme as described in H. Seyedi and S. Tanhaeidilmaghani, “New Controlled Switching Approach for Limitation of Transmission Line Switching Overvoltages,” in IET Generation, Transmission Distribution, vol. 7, no. 3, pp. 218-225, 2013. This scheme is referred to herein as a method of half of the peak voltage, because its closing operation is performed at the instant of +Vₘₐₓ/2 of the source side voltage if the polarity of trapped charge is positive, and at the instant of −Vₘₐₓ/2 if the polarity of trapped charge is positive negative. Interested readers can refer to the cited paper to understand the mathematical formulation and the advantage of this application.

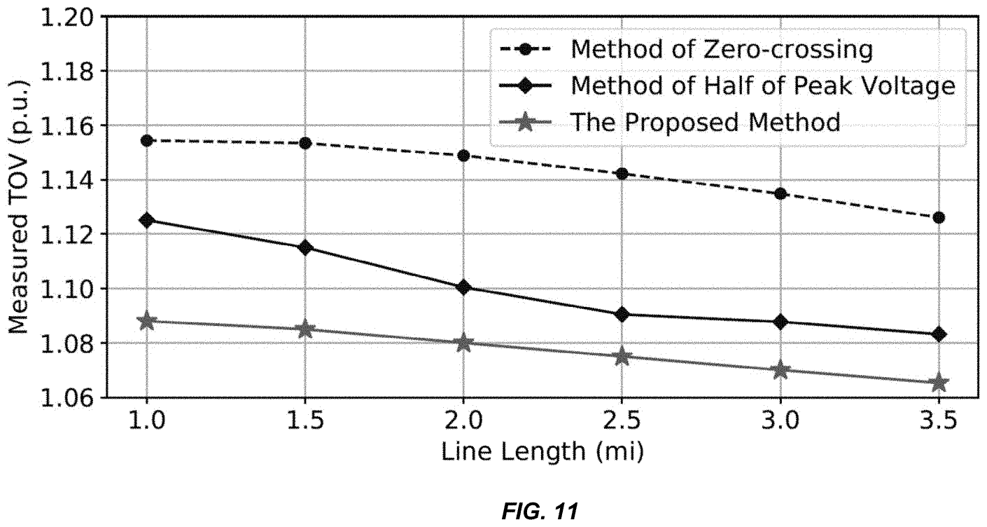

FIG. 11 is a graphical representation of a comparison of the proposed methodology with both traditional methods. That comparison is drawn by varying the line lengths from 1 mile to 3.5 miles with an increment of 0.5 mile and measuring the root mean square (rms) voltage at the beginning of the cable. It clearly indicates that the proposed method outperforms the past techniques because the measured TOVs are the least. Additionally, FIG. 11 illustrates a key observation about the relationship between line length and TOVs. It can be visualized that as the line length increases, the TOVs tend to decrease. Such a phenomenon is due to the progressive addition of resistance that is responsible for consuming the energy (due to the trapped charge) at reclosure operation.

VI. Discussions

There are very challenging issues in TOV modeling. Realistic TOV should consider the modeling of restrikes/prestrikes, capacitive current, inductive current switching, the structure of the network, system parameters, whether or not virtual chopping takes place, chopping current, the instant of opening, and resonance phenomena, etc.

Although it relates to transmission, TOV calculations are used to determine minimum approach distance (MAD) for the work rules required by the National Electrical Safety Code (NESC) and OSHA (1910.269(I)(3)(ii)). TOV is also dependent on line design and operation. The work in S. Surges, “Switching Surges: Part IV-Control and Reduction on AC Transmission Lines,” IEEE Transactions on Power Apparatus and Systems, no. 8, pp. 2694-2702,1982, provides guidance on TOV factors and methods for control. OSHA 1926 Table 5 in Appendix A to Subpart V, provides TOV values based on various causes.

Restrikes can influence TOV, but the industry generally believes that proper periodic breaker maintenance limits the likelihood of restrikes. The periodic maintenance of distribution system breakers is assumed to have a similar effect. Meanwhile, capacitor switching may have restrikes, but embodiments described herein focus on feeder breaking reclosing while attempting to clear a fault. During this time, the state of a switched capacitor bank remains unchanged, as well as any other devices connected to this circuit. It is also assumed that a circuit under a fault condition is not lightly loaded.

Limitations exist in TOV modeling, but this disclosure has demonstrated an innovative learning method that controls the reclosing under a spectral of system complexity. It relies on reinforcement learning to explore the complicated state space in a model-free way, no matter what the restrike/prestrike model is, what the structures of the network are, what the system parameters are, and whether an additional preventive device is added. Promising results are shown in the numerical section.

VII. Process for Recloser Control in a Power Distribution System

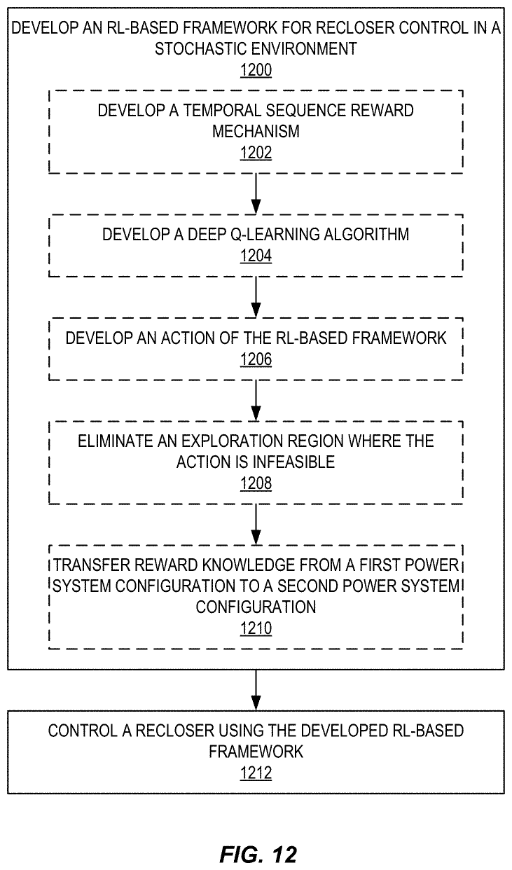

FIG. 12 is a flow diagram illustrating a process for recloser control in a power distribution system. Dashed boxes represent optional steps. The process begins at operation 1200, with developing an RL-based framework for recloser control in a stochastic environment. In an exemplary aspect, the RL-based framework is a model-free machine learning framework. Operation 1200 optionally includes a number of additional operations, beginning with operation 1202, with developing a temporal sequence reward mechanism. Operation 1200 optionally continues at operation 1204, with developing a deep Q-learning algorithm.

Operation 1200 optionally continues at operation 1206, with developing an action of the RL-based framework. Operation 1200 optionally continues at operation 1208, with eliminating an exploration region where the action is infeasible. Operation 1200 optionally continues at operation 1210, with transferring reward knowledge from a first power system configuration to a second power system configuration.

After operation 1200, the process continues at operation 1212, with controlling a recloser using the developed RL-based framework.

Although the operations of FIG. 12 are illustrated in a series, this is for illustrative purposes and the operations are not necessarily order dependent. Some operations may be performed in a different order than that presented. For example, operations 1202, 1204, 1206, and 1210 may occur in various different orders, and some or all may be performed concurrently. Further, processes within the scope of this disclosure may include fewer or more steps than those illustrated in FIG. 12.

VIII. Computer System

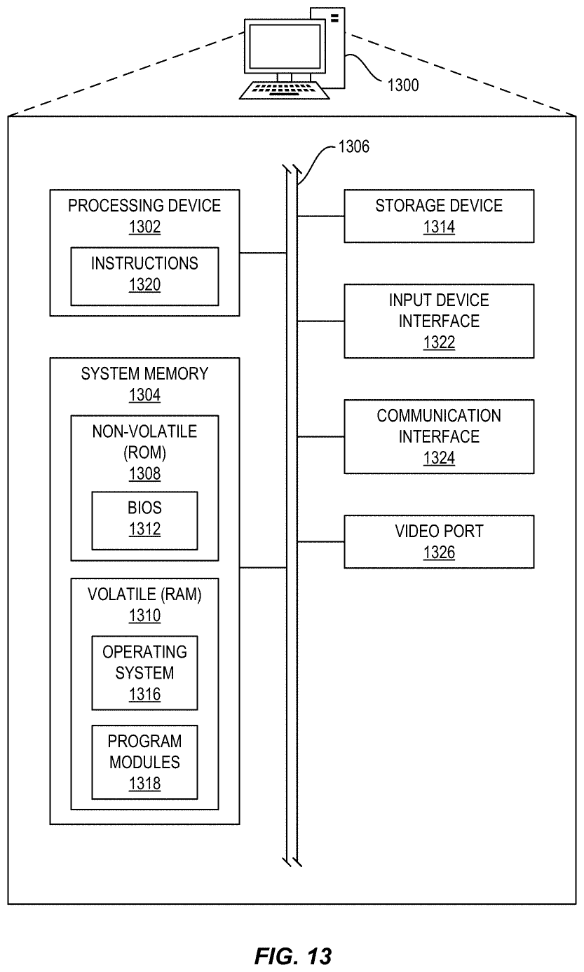

FIG. 13 is a block diagram of a recloser controller suitable for implementing RL-based recloser control for distribution cables with degraded insulation level according to embodiments disclosed herein. The recloser controller includes or is implemented as a computer system 1300, which comprises any computing or electronic device capable of including firmware, hardware, and/or executing software instructions that could be used to perform any of the methods or functions described above. In this regard, the computer system 1300 may be a circuit or circuits included in an electronic board card, such as a printed circuit board (PCB), a server, a personal computer, a desktop computer, a laptop computer, an array of computers, a personal digital assistant (PDA), a computing pad, a mobile device, or any other device, and may represent, for example, a server or a user's computer.

The exemplary computer system 1300 in this embodiment includes a processing device 1302 or processor, a system memory 1304, and a system bus 1306. The system memory 1304 may include non-volatile memory 1308 and volatile memory 1310. The non-volatile memory 1308 may include read-only memory (ROM), erasable programmable read-only memory (EPROM), electrically erasable programmable read-only memory (EEPROM), and the like. The volatile memory 1310 generally includes random-access memory (RAM) (e.g., dynamic random-access memory (DRAM), such as synchronous DRAM (SDRAM)). A basic input/output system (BIOS) 1312 may be stored in the non-volatile memory 1308 and can include the basic routines that help to transfer information between elements within the computer system 1300.

The system bus 1306 provides an interface for system components including, but not limited to, the system memory 1304 and the processing device 1302. The system bus 1306 may be any of several types of bus structures that may further interconnect to a memory bus (with or without a memory controller), a peripheral bus, and/or a local bus using any of a variety of commercially available bus architectures.

The processing device 1302 represents one or more commercially available or proprietary general-purpose processing devices, such as a microprocessor, central processing unit (CPU), or the like. More particularly, the processing device 1302 may be a complex instruction set computing (CISC) microprocessor, a reduced instruction set computing (RISC) microprocessor, a very long instruction word (VLIW) microprocessor, a processor implementing other instruction sets, or other processors implementing a combination of instruction sets. The processing device 1302 is configured to execute processing logic instructions for performing the operations and steps discussed herein.

In this regard, the various illustrative logical blocks, modules, and circuits described in connection with the embodiments disclosed herein may be implemented or performed with the processing device 1302, which may be a microprocessor, field programmable gate array (FPGA), a digital signal processor (DSP), an application-specific integrated circuit (ASIC), or other programmable logic device, a discrete gate or transistor logic, discrete hardware components, or any combination thereof designed to perform the functions described herein. Furthermore, the processing device 1302 may be a microprocessor, or may be any conventional processor, controller, microcontroller, or state machine. The processing device 1302 may also be implemented as a combination of computing devices (e.g., a combination of a DSP and a microprocessor, a plurality of microprocessors, one or more microprocessors in conjunction with a DSP core, or any other such configuration).

The computer system 1300 may further include or be coupled to a non-transitory computer-readable storage medium, such as a storage device 1314, which may represent an internal or external hard disk drive (HDD), flash memory, or the like. The storage device 1314 and other drives associated with computer-readable media and computer-usable media may provide non-volatile storage of data, data structures, computer-executable instructions, and the like. Although the description of computer-readable media above refers to an HDD, it should be appreciated that other types of media that are readable by a computer, such as optical disks, magnetic cassettes, flash memory cards, cartridges, and the like, may also be used in the operating environment, and, further, that any such media may contain computer-executable instructions for performing novel methods of the disclosed embodiments.

An operating system 1316 and any number of program modules 1318 or other applications can be stored in the volatile memory 1310, wherein the program modules 1318 represent a wide array of computer-executable instructions corresponding to programs, applications, functions, and the like that may implement the functionality described herein in whole or in part, such as through instructions 1320 on the processing device 1302. The program modules 1318 may also reside on the storage mechanism provided by the storage device 1314. As such, all or a portion of the functionality described herein may be implemented as a computer program product stored on a transitory or non-transitory computer-usable or computer-readable storage medium, such as the storage device 1314, volatile memory 1310, non-volatile memory 1308, instructions 1320, and the like. The computer program product includes complex programming instructions, such as complex computer-readable program code, to cause the processing device 1302 to carry out the steps necessary to implement the functions described herein.

An operator, such as the user, may also be able to enter one or more configuration commands to the computer system 1300 through a keyboard, a pointing device such as a mouse, or a touch-sensitive surface, such as the display device, via an input device interface 1322 or remotely through a web interface, terminal program, or the like via a communication interface 1324. The communication interface 1324 may be wired or wireless and facilitate communications with any number of devices via a communications network in a direct or indirect fashion. An output device, such as a display device, can be coupled to the system bus 1306 and driven by a video port 1326. Additional inputs and outputs to the computer system 1300 may be provided through the system bus 1306 as appropriate to implement embodiments described herein.

The operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined.

Those skilled in the art will recognize improvements and modifications to the preferred embodiments of the present disclosure. All such improvements and modifications are considered within the scope of the concepts disclosed herein and the claims that follow.

What is claimed is:

1. A method for recloser control in a power distribution system, the method comprising:
developing a reinforcement learning (RL)-based framework for recloser control in a stochastic environment; and
controlling a recloser using the developed RL-based framework.

2. The method of claim 1, wherein the RL-based framework is a model-free machine learning framework.

3. The method of claim 1, wherein developing the RL-based framework comprises developing a temporal sequence reward mechanism.

4. The method of claim 3, wherein developing the RL-based framework further comprises developing a deep Q-learning algorithm.

5. The method of claim 4, wherein an overall learning curve of the developed RL-based framework uses the temporal sequence reward mechanism and a plurality of hyper-parameters.

6. The method of claim 5, wherein the plurality of hyper-parameters comprises two or more of the following: discounting factor (γ), epsilon (ε), decay rate, smoothing factor (τ), experience buffer ( [symbol] ), and minimum batch size (M).

7. The method of claim 1, wherein developing the RL-based framework comprises developing an action of the RL-based framework.

8. The method of claim 7, wherein developing the RL-based framework further comprises eliminating an exploration region where the action is infeasible.

9. The method of claim 8, wherein eliminating the exploration region where the action is infeasible comprises using a varying probability approach to yield a fast learning curve for the RL-based framework.

10. The method of claim 1, wherein the RL-based framework is adaptive to untrained power system configurations.

11. The method of claim 10, wherein developing the RL-based framework comprises transferring reward knowledge from a first power system configuration to a second power system configuration.

12. A recloser controller, comprising:
a processing device; and
a memory comprising a set of instructions which, when executed by the processing device, cause the recloser controller to:
develop a state, action, and reward of a reinforcement learning (RL)-based framework to mitigate reclosing transient overvoltage (TOV) in a recloser.

13. The recloser controller of claim 12, wherein the reward of the RL-based framework comprises a temporal sequence reward mechanism.

14. The recloser controller of claim 13, wherein the RL-based framework comprises a model-free machine learning framework.

15. The recloser controller of claim 14, wherein the model-free machine learning framework comprises a deep Q-network (DQN).

16. The recloser controller of claim 13, wherein an overall learning curve of the developed RL-based framework uses the temporal sequence reward mechanism and a plurality of hyper-parameters including at least one of the following: discounting factor (γ), epsilon (ε), decay rate, smoothing factor (τ), experience buffer ( [symbol] ), and minimum batch size (M).

17. The recloser controller of claim 12, wherein the recloser controller provides control of the recloser using the RL-based framework.

18. The recloser controller of claim 12, wherein the recloser controller is embedded within the recloser.

19. The recloser controller of claim 12, wherein the RL-based framework uses infeasible action space elimination to increase learning speed.

20. The recloser controller of claim 12, wherein the RL-based framework uses post-learning knowledge transfer to generalize from a trained environment to an untrained environment.
